(19) United States
(12) Patent Application Publication
(10) Pub. No.: US 2012/0126334 A1
(43) Pub. Date: May 24, 2012

(54) BREAKDOWN VOLTAGE IMPROVEMENT WITH A FLOATING SUBSTRATE

(75) Inventors: Ru-Yi Su, Kouhu Township (TW); Chia-Chin Shen, Hsinchu City (TW); Yu Chuan Liang, Hsinchu City (TW); Fu-Chih Yang, Fengshan City (TW); Chun Lin Tsai, Hsin-Chu (TW); Chih-Chang Cheng, Hsinchu City (TW); Ruey-Hsin Liu, Hsin-Chu (TW)

(73) Assignee: TAIWAN SEMICONDUCTOR MANUFACTURING COMPANY, LTD., Hsinchu City (TW)

(21) Appl. No.: 12/953,665

(22) Filed: Nov. 24, 2010

(51) Int. Cl. H01L 29/78; H01L 21/336

(52) U.S. Cl. 257/380; 438/238; 257/E29.255; 257/E21.409

(57) ABSTRACT

The present disclosure provides a semiconductor device that includes a substrate having a resistor element region and a transistor region, a floating substrate in the resistor element region of the substrate, an epitaxial layer disposed over the floating substrate, and an active region defined in the epitaxial layer, the active region surrounded by isolation structures. The device further includes a resistor block disposed over an isolation structure, and a dielectric layer disposed over the resistor block, the isolation structures, and the active region. A method of fabricating such semiconductor devices is also provided.

### BACKGROUND

In the design of semiconductor integrated circuits (ICs), there are several areas of concern. One has been the limited breakdown voltage capability of ICs for general applications. Prior circuits have utilized a grounded substrate underneath polysilicon resistor blocks but the breakdown voltage of such circuits has been limited to about 500V.

Accordingly, methods of semiconductor device fabrication with improved breakdown voltage capability and devices fabricated by such methods are desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A and 1B are flowcharts illustrating methods for fabricating a semiconductor device with improved breakdown voltage capability according to various aspects of the present disclosure.

FIG. 2 is a graph illustrating an improved breakdown voltage of a semiconductor device according to various aspects of the present disclosure.

FIG. 3 is an example circuit diagram of a semiconductor device according to the various aspects of the present disclosure.

FIG. 4 is a cross-sectional view of an embodiment of a semiconductor device including a floating substrate for improved breakdown voltage capability according to various aspects of the present disclosure.

FIG. 5 is a cross-sectional view of another embodiment of a semiconductor device including a floating substrate for improved breakdown voltage capability according to various aspects of the present disclosure.

FIGS. 6A through 6F are cross-sectional views of the semiconductor device of FIG. 5 at various stages of fabrication according to various aspects of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

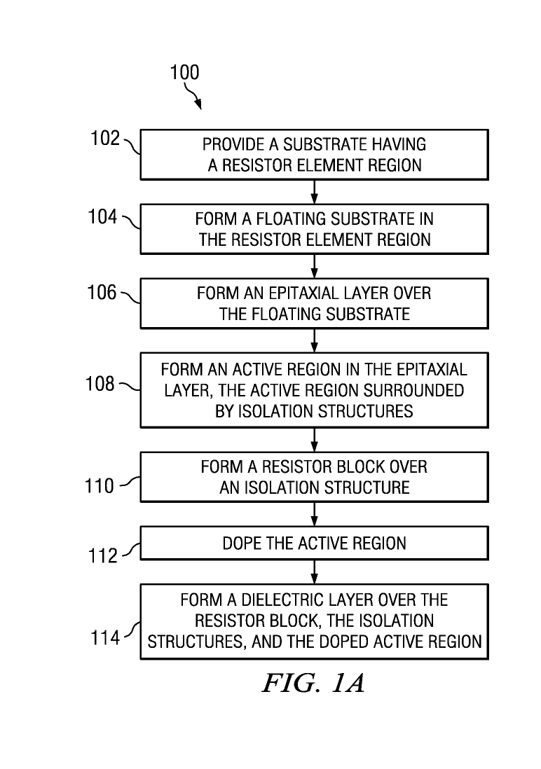

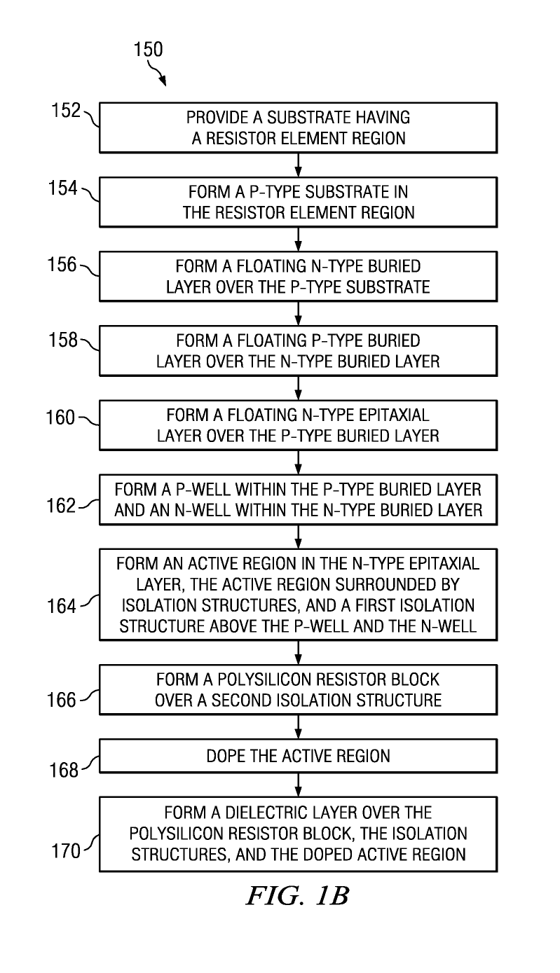

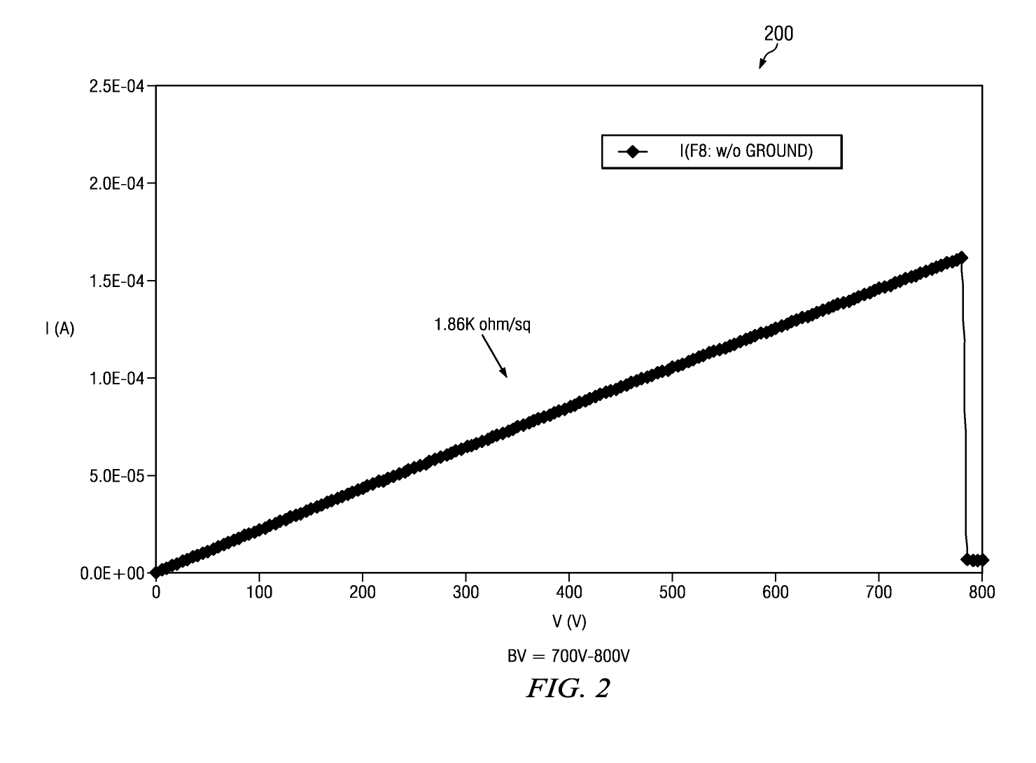

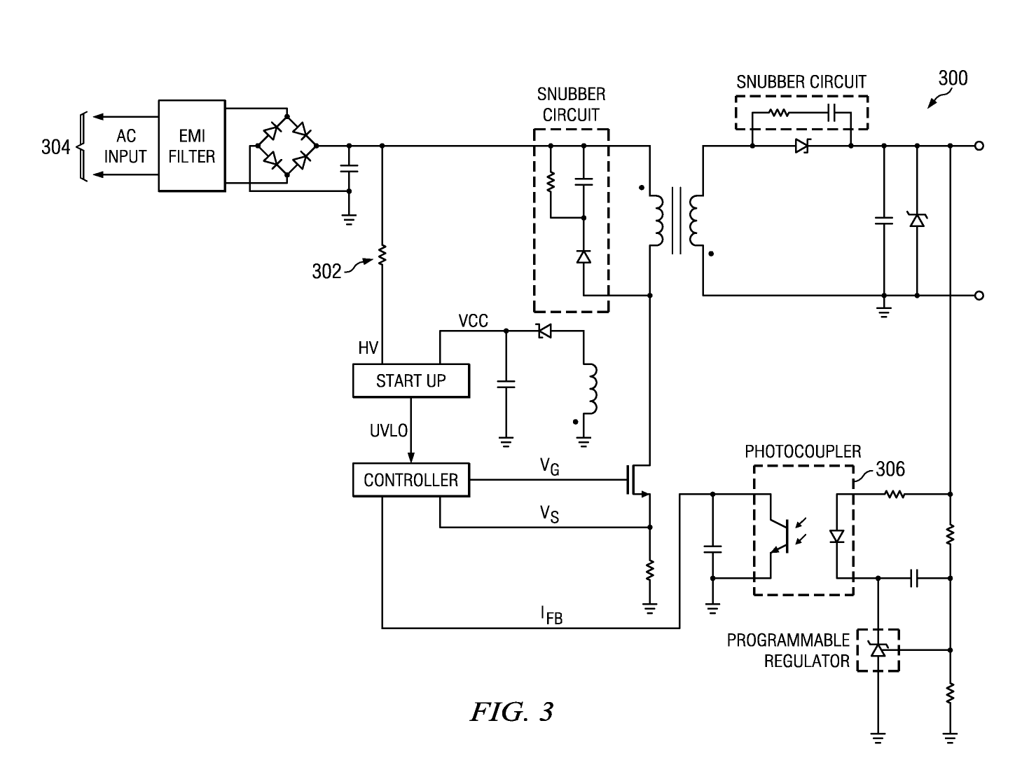

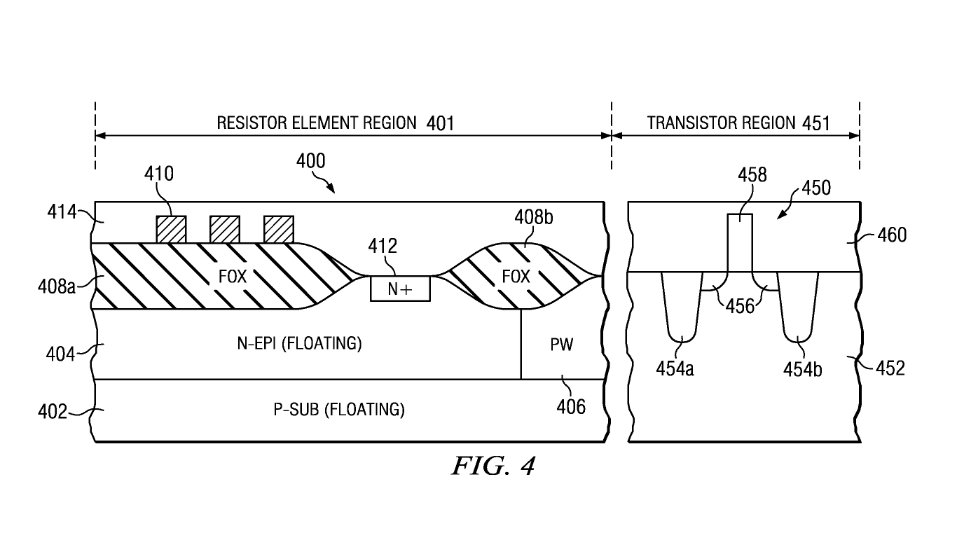

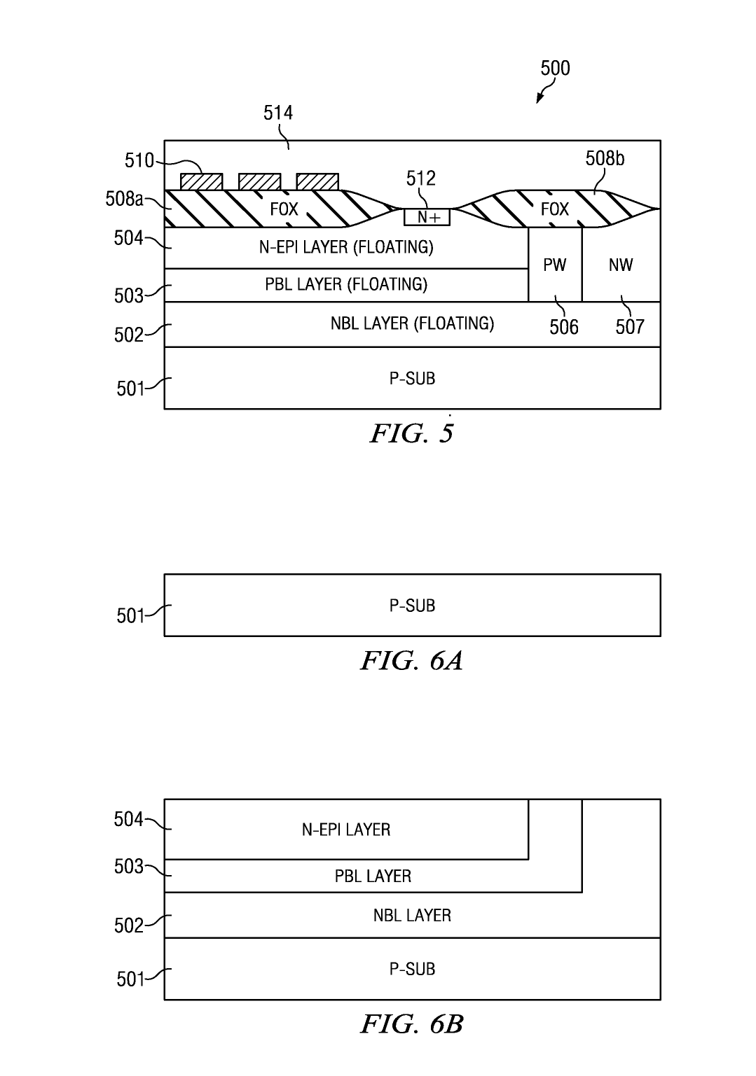

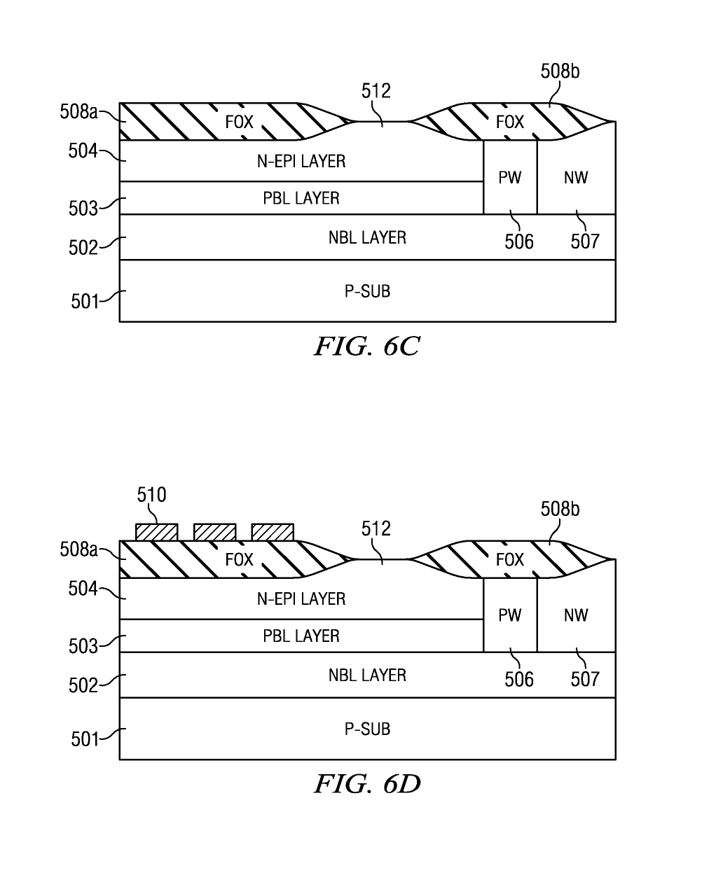

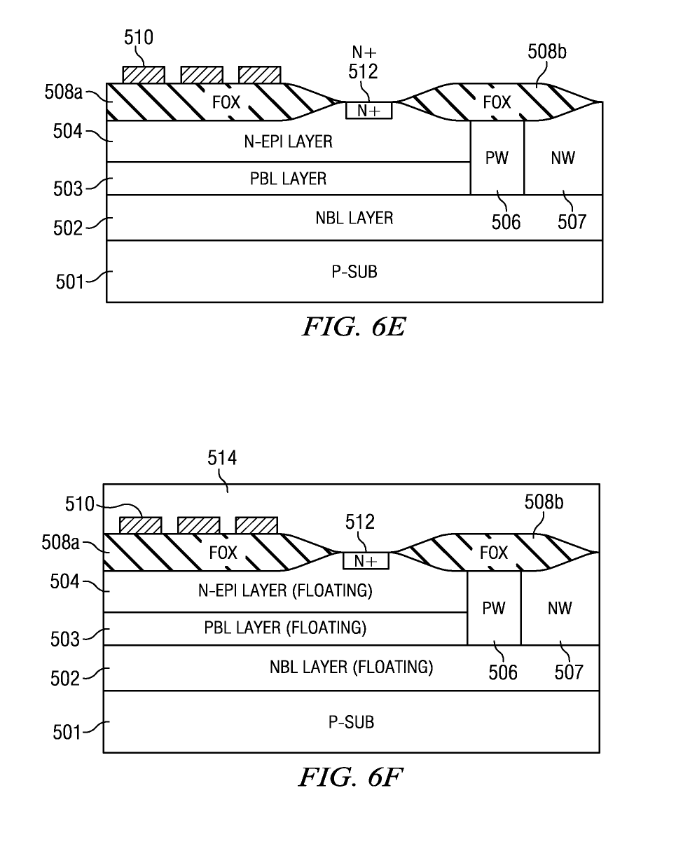

Referring to the figures, FIG. 1A and 1B illustrate flowcharts of a method 100 and a method 150, respectively, for fabricating a semiconductor device with a floating substrate for improving breakdown voltage capability according to various aspects of the present disclosure. FIG. 2 is a graph illustrating an improved breakdown voltage of a semiconductor device according to various aspects of the present disclosure, and FIG. 3 is an example circuit diagram 300 of a semiconductor device according to the various aspects of the present disclosure. FIG. 4 is a cross-sectional view of an embodiment of a semiconductor device 400 including a floating substrate for improved breakdown voltage capability according to various aspects of the present disclosure, and FIG. 5 is a cross-sectional view of an embodiment of a semiconductor device 500 including a floating substrate for improved breakdown voltage capability according to various aspects of the present disclosure. FIGS. 6A through 6F are cross-sectional views of the semiconductor device 500 of FIG. 5 at various stages of fabrication according to various aspects of the present disclosure. The semiconductor devices 400 and 500 may include similar features, and accordingly, similar features are similarly numbered for the sake of simplicity and clarity.

It should be noted that part of the semiconductor devices 400 and 500 might be fabricated with a CMOS process flow. Accordingly, it is understood that additional processes may be provided before, during, and after the methods 100 and 150 of FIG. 1A and 1B, respectively, and that some other processes may only be briefly described herein. The semiconductor devices 400 and 500 may be fabricated in a gate last process (also referred to as a replacement poly gate process (RPG)) in one example. In a gate last process, a dummy gate structure (e.g., formed of polysilicon (or poly)) may be initially formed in both a region for a seal ring and a region for a circuit, and may be followed by a normal CMOS process flow until deposition of an interlayer dielectric (ILD). The dummy poly gate structure in the circuit region may then be removed and replaced with a high-k gate dielectric/metal gate structure.

Referring now to FIG. 1A, method 100 begins with block 102 in which a semiconductor substrate is provided having a resistor element region and a transistor region. In an embodiment, the resistor element region is for forming a high voltage resistor element of a device, and the transistor region is for forming at least a transistor device therein. The method 100 continues with block 104 in which a floating substrate is formed in the resistor element region, and with block 106 in which an epitaxial layer is formed over the floating substrate. The method 100 continues with block 108 in which an active region is formed in the epitaxial layer with isolation structures surrounding the active region. At block 110, at least one resistor block is formed over an isolation structure, and at block 112, the active region is doped, for example with an n-type dopant. In other embodiments, the order of the processes in blocks 110 and 112 may be switched. At block 114, a dielectric layer is formed over the resistor block, the isolation structures, and the doped active region.

Referring now to FIG. 1B, method 150 begins with block 152 in which a semiconductor substrate is provided having a resistor element region and a transistor region. In an embodiment, the resistor element region is for forming a high voltage resistor element of a device, and the transistor region is for forming at least a transistor device therein. The method 100 continues with the formation of a floating substrate, including block 154 in which a p-type substrate is formed in the resistor element region, block 156 in which a floating n-type buried layer is formed over the p-type substrate, and block 158 in which a floating p-type buried layer is formed over the floating n-type buried layer. The method continues with block 160 in which a floating n-type epitaxial layer is formed over the p-type buried layer. At block 162, a p-well is formed within the p-type buried layer and an n-well is formed within the n-type buried layer. At block 164, an active region is formed in the epitaxial layer with isolation structures surrounding the active region and a first isolation structure disposed above the p-well and the n-well. At block 166, at least one resistor block is formed over a second isolation structure, and at block 168, the active region is doped, for example with an n-type dopant. In other embodiments, the order of the processes in blocks 166 and 168 may be switched. At block 170, a dielectric layer is formed over the resistor block, the isolation structures, and the doped active region.

As noted above, it is understood that additional processes may be provided before, during, and after the methods 100 and 150 of FIG. 1A and 1B. For example, after the dielectric layer is formed in blocks 114 and 170 of FIG. 1A and 1B, respectively, contact bars, metal layers, vias, interlayer dielectrics, and passivation layers may be formed above the active region. Wafer acceptance testing processes may be subsequently performed as well.

Referring now to FIG. 2, a graph 200 illustrates an improved breakdown voltage of a semiconductor device according to various aspects of the present disclosure. The y-axis is for current and the x-axis is for voltage, with the slope showing a high voltage resistance of the circuit device, and the data is for a semiconductor device having a floating substrate under resistor blocks of the circuit device (i.e., the substrate is without ground). A breakdown voltage between about 700 V and about 800 V are available with a semiconductor device having a floating substrate in accordance with aspects of the present disclosure.

Referring now to FIG. 3, an example circuit diagram 300 is illustrated of a semiconductor device according to the various aspects of the present disclosure. A high voltage resistor 302 is shown between an AC input 304 and a photocoupler 306, the resistor providing for an improved breakdown voltage of the circuit device.

Referring now to FIG. 4, a cross-sectional view is illustrated of an embodiment of a semiconductor device 400 including a floating substrate for improved breakdown voltage capability at a stage of fabrication according to the method 100 of FIG. 1. Semiconductor device 400 includes a semiconductor substrate, such as a silicon substrate, having a resistor element region 401 and a transistor region 451. The substrate, (e.g., substrates 402, 452) may be comprised of silicon, or alternatively may include silicon germanium, gallium arsenic, or other suitable semiconductor materials. The substrate may further include doped active regions and other features such as a buried layer, and/or an epitaxy layer. Furthermore, the substrate may be a semiconductor on insulator such as silicon on insulator (SOI). In other embodiments, the semiconductor substrate may include a doped epitaxy layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure. The active region may be configured as an NMOS device (e.g., nFET) or a PMOS device (e.g., pFET). The semiconductor substrate may include underlying layers, devices, junctions, and other features (not shown) formed during prior process steps or which may be formed during subsequent process steps.

In one embodiment, semiconductor device 400 includes a floating substrate 402 in the resistor element region 401, such as one doped with a p-type dopant, and a floating epitaxial layer 404 formed above the floating substrate 402. The epitaxial layer 404 may be doped with an n-type dopant in one example. A p-well 406 may be formed within the floating substrate 402 and adjacent to the epitaxial layer 404. An active region 412 is defined in the epitaxial layer 404 between isolation structures 408a and 408b, such as shallow trench isolation (STI) structures or local oxidation of semiconductor (LOCOS) structures. Active region 412 may be subsequently doped with an n-type dopant in one example. An isolation structure, such as isolation structure 408b, may be formed above p-well 406. At least one resistor block 410 is disposed over an isolation structure, such as isolation structure 408a. In one example, resistor block 410 may be comprised of polysilicon, although other materials are within the scope of the present disclosure. A dielectric layer 414 is disposed over the resistor block 410, the isolation structures 408a, 408b, and the active region 412.

In one embodiment, semiconductor device 400 includes a transistor 450 over a substrate 452 in the transistor region 451. Transistor 450 includes isolation structures 454a and 454b, such as shallow trench isolation (STI) or LOCOS features formed in the substrate 452 for isolating active regions 456 (e.g., source and drain with a channel therebetween) from other regions of the substrate 452. The active regions may be configured as an NMOS device (e.g., nFET) or as a PMOS device (e.g., pFET) in one example.

Advantageously, substrate 402 is floating (i.e., substrate 402 is not maintained at ground; or there is no ohmic contact between substrate 402 and a ground) underneath resistor block 410 to increase the breakdown voltage capability of the semiconductor device.

FIG. 5 is a cross-sectional view of an embodiment of a semiconductor device 500 in the resistor element region including a floating substrate for improved breakdown voltage capability according to aspects of the present disclosure. The semiconductor devices 400 and 500 may include similar features, and accordingly, similar features are similarly numbered for the sake of simplicity and clarity. Descriptions of substantially similar features as described above with respect to FIG. 4 may not be included here to avoid prolix description although fully applicable in this embodiment.

In one embodiment, device 500 includes a p-type substrate 501 in a resistor element region, a floating n-type buried layer 502 disposed over the p-type substrate 501, and a floating p-type buried layer 503 disposed over the n-type buried layer 502. A floating n-type epitaxial layer 504 may then be disposed over the p-type buried layer 503. A p-well 506 may be formed within the floating p-type buried layer 503, and an n-well 507 may be formed within the n-type buried layer 502. An active region 512 is defined in the epitaxial layer 504 between isolation structures 508a and 508b, such as shallow trench isolation (STI) structures or local oxidation of semiconductor (LOCOS) structures. Active region 512 may be subsequently doped with an n-type dopant in one example. An isolation structure, such as isolation structure 508b, may be formed above p-well 506 and n-well 507. At least one resistor block 510 is disposed over an isolation structure, such as isolation structure 508a. In one example, resistor block 510 may be comprised of polysilicon, although other materials are within the scope of the present disclosure. A dielectric layer 514 is disposed over the resistor block 510, the isolation structures 508a, 508b, and the active region 512.

Referring now to FIG. 6A through 6F, cross-sectional views of the semiconductor device 500 of FIG. 5 are illustrated at various stages of fabrication according to various aspects of the present disclosure. FIG. 6A illustrates substrate 501 in a resistor element region. As noted above, substrate 501 may be a semiconductor substrate doped with a p-type dopant. The substrate 501 may be comprised of silicon, or alternatively may include silicon germanium, gallium arsenic, or other suitable semiconductor materials. The substrate may further include doped active regions and other features such as a buried layer, and/or an epitaxy layer. Furthermore, the substrate may be a semiconductor on insulator such as silicon on insulator (SOI). In other embodiments, the semiconductor substrate may include a doped epitaxy layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure. The active region may be configured as an NMOS device (e.g., nFET) or a PMOS device (e.g., pFET). The semiconductor substrate may include underlying layers, devices, junctions, and other features (not shown) formed during prior process steps or which may be formed during subsequent process steps.

FIG. 6B illustrates the formation of floating n-type buried layer 502 disposed over the p-type substrate 501, floating p-type buried layer 503 disposed over the n-type buried layer 502, and floating n-type epitaxial layer 504 disposed over the p-type buried layer 503. In one example, the n-type buried layer 502 is formed by doping the substrate with a n-type dopant at a concentration between about 1E15 cm⁻³ and about 1E16 cm⁻³, the p-type buried layer 503 is formed by doping the substrate with a p-type dopant at a concentration between about 1E17 cm⁻³ and about 1E18 cm⁻³, and the epitaxial layer 504 is formed by conventional deposition techniques to have a resistivity of about 45 ohm-cm.

FIG. 6C illustrates the formation of p-well 506 within the floating p-type buried layer 503, and n-well 507 within the n-type buried layer 502. In one example, the p-well 506 is formed by doping the substrate with a p-type dopant at a concentration between about 1E16 cm⁻³ and about 1E17 cm⁻³, and the n-well 507 is formed by doping the substrate with a n-type dopant at a concentration between about 1E16 cm⁻³ and about 1E17 cm⁻³. Active region 512 is defined in the epitaxial layer 504 between isolation structures 508a and 508b, such as shallow trench isolation (STI) structures or local oxidation of semiconductor (LOCOS) structures. An isolation structure, such as isolation structure 508b, may be formed above p-well 506 and n-well 507.

FIG. 6D illustrates the formation of at least one resistor block 510 disposed over an isolation structure, such as isolation structure 508a. In one example, resistor block 510 may be comprised of polysilicon, although other materials are within the scope of the present disclosure. Various deposition, patterning, and/or etching techniques and processes may be used to form resistor blocks 510.

FIG. 6E illustrates the doping of active region 512, with an n-type dopant in one example.

FIG. 6F illustrates the formation of dielectric layer 514 over the resistor block 510, the isolation structures 508a, 508b, and the active region 512. Dielectric layer 514 may be comprised of various dielectrics, such as various oxides, and may be formed by various conventional deposition and/or growth techniques and processes, such as a high aspect ratio process (HARP) and/or a high density plasma (HDP) CVD process.

Advantageously, n-type buried layer 502, p-type buried layer 503, and n-type epitaxial layer 504 function as floating layers (i.e., the layers 502, 503, and 504 are not maintained at ground; or there is no ohmic contact between the layers 502, 503, and 504, and a ground) underneath resistor block 510 to increase the breakdown voltage capability of the semiconductor device.

As noted above, it is understood that additional processes may be provided before, during, and after the formation of dielectric layer 514. For example, after the dielectric layer is formed, contact bars, metal layers, vias, interlayer dielectrics, and passivation layers may be formed above the active region. Additional processes such as chemical mechanical polish and wafer acceptance testing processes may be subsequently performed as well. It is further noted that where a particular p-type or n-type dopant is described above, the complementary type of dopant may be used (i.e., p-type and n-type dopants may be switched in the descriptions above).

The present disclosure provides for many different embodiments. One of the broader forms of the present disclosure involves a semiconductor device. The semiconductor device includes a substrate having a resistor element region and a transistor region, a floating substrate in the resistor element region of the substrate, an epitaxial layer disposed over the floating substrate, and an active region defined in the epitaxial layer, the active region surrounded by isolation structures. The device further includes a resistor block disposed over an isolation structure, and a dielectric layer disposed over the resistor block, the isolation structures, and the active region.

Another of the broader forms of the present disclosure involves a semiconductor device including a substrate having a resistor element region and a transistor region, a p-type substrate in the resistor element region of the substrate, a floating n-type buried layer disposed over the p-type substrate, a floating p-type buried layer disposed over the n-type buried layer, a floating n-type epitaxial layer disposed over the p-type buried layer, a p-well disposed within the p-type buried layer, a n-well disposed within the n-type buried layer, and an active region defined in the n-type epitaxial layer, the active region surrounded by isolation structures, with a first isolation structure disposed above the p-well and the n-well. The device further includes a polysilicon resistor block disposed over a second isolation structure, and a dielectric layer disposed over the polysilicon resistor block, the isolation structures, and the active region.

Another of the broader forms of the present disclosure involves a method of fabricating a semiconductor device. The method includes providing a substrate having a resistor element region and a transistor region, forming a floating substrate in the resistor element region of the substrate, forming an epitaxial layer over the floating substrate, and forming an active region in the epitaxial layer, the active region surrounded by isolation structures. The method further includes forming a resistor block over an isolation structure, doping the active region, and forming a dielectric layer over the resistor block, the isolation structures, and the doped active region.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a substrate having a resistor element region and a transistor region;
a floating substrate in the resistor element region of the substrate;
an epitaxial layer disposed over the floating substrate;
an active region defined in the epitaxial layer, the active region surrounded by isolation structures;
a resistor block disposed over an isolation structure; and
a dielectric layer disposed over the resistor block, the isolation structures, and the active region.

2. The semiconductor device of claim 1, wherein the floating substrate is doped with a p-type dopant, the epitaxial layer is doped with an n-type dopant, and the active region is doped with an n-type dopant.

3. The semiconductor device of claim 1, wherein the epitaxial layer is a floating layer.

4. The semiconductor device of claim 1, wherein the isolation structures include one of shallow trench isolation (STI) structures or local oxidation of semiconductor (LOCOS) structures.

5. The semiconductor device of claim 1, wherein an isolation structure is formed above a p-well.

6. A semiconductor device, comprising:
a substrate having a resistor element region and a transistor region;
a p-type substrate in the resistor element region of the substrate;
a floating n-type buried layer disposed over the p-type substrate;
a floating p-type buried layer disposed over the n-type buried layer;
a floating n-type epitaxial layer disposed over the p-type buried layer;
a p-well disposed within the p-type buried layer;
an n-well disposed within the n-type buried layer;
an active region defined in the n-type epitaxial layer, the active region surrounded by isolation structures, with a first isolation structure disposed above the p-well and the n-well;
a polysilicon resistor block disposed over a second isolation structure; and
a dielectric layer disposed over the polysilicon resistor block, the isolation structures, and the active region.

7. The semiconductor device of claim 6, wherein the n-type buried layer is doped with an n-type dopant at a concentration between about 1E15 cm⁻³ and about 1E16 cm⁻³.

8. The semiconductor device of claim 6, wherein the p-type buried layer is doped with a p-type dopant at a concentration between about 1E17 cm⁻³ and about 1E18 cm⁻³.

9. The semiconductor device of claim 6, wherein the n-type epitaxial layer has a resistivity of about 45 ohm-cm.

10. The semiconductor device of claim 6, wherein the p-well is doped with a p-type dopant at a concentration between about 1E16 cm⁻³ and about 1E17 cm⁻³.

11. The semiconductor device of claim 6, wherein the n-well is doped with an n-type dopant at a concentration between about 1E16 cm⁻³ and about 1E17 cm⁻³.

12. The semiconductor device of claim 6, wherein the active region is doped with an n-type dopant.

13. A method of fabricating a semiconductor device, the method comprising:
providing a substrate having a resistor element region and a transistor region;
forming a floating substrate in the resistor element region of the substrate;
forming an epitaxial layer over the floating substrate;
forming an active region in the epitaxial layer, the active region surrounded by isolation structures;
forming a resistor block over an isolation structure;
doping the active region; and
forming a dielectric layer over the resistor block, the isolation structures, and the doped active region.

14. The method of claim 13, wherein forming the floating substrate includes forming a p-type substrate in the resistor element region of the substrate, forming a floating n-type buried layer over the p-type substrate, and forming a floating p-type buried layer over the floating n-type buried layer.

15. The method of claim 14, wherein the n-type buried layer is doped with an n-type dopant at a concentration between about 1E15 cm⁻³ and about 1E16 cm⁻³.

16. The method of claim 14, wherein the p-type buried layer is doped with a p-type dopant at a concentration between about 1E17 cm⁻³ and about 1E18 cm⁻³.

17. The method of claim 14, further comprising doping the p-type buried layer with a p-type dopant at a concentration between about 1E16 cm⁻³ and about 1E17 cm⁻³ to form a p-well under an isolation structure.

18. The method of claim 14, further comprising doping the n-type buried layer with a n-type dopant at a concentration between about 1E16 cm⁻³ and about 1E17 cm⁻³ to form a n-well under an isolation structure.

19. The method of claim 13, wherein the epitaxial layer is formed as a floating layer to have a resistivity of about 45 ohm-cm.

20. The method of claim 13, wherein the active region is doped with an n-type dopant.
